(19) United States
(12) Patent Application Publication
(10) Pub. No.: US 2020/0010200 A1
(43) Pub. Date: Jan. 9, 2020

(54) VEHICLE BODY AND UNMANNED AERIAL VEHICLE

(71) Applicant: SZ DJI TECHNOLOGY CO., LTD., Shenzhen (CN)

(72) Inventors: Xiangyu CHEN, Shenzhen (CN); Li QIU, Shenzhen (CN); Mingxi WANG, Shenzhen (CN)

(21) Appl. No.: 16/549,353

(22) Filed: Aug. 23, 2019

Related U.S. Application Data
(63) Continuation of application No. PCT/CN2017/074819, filed on Feb. 24, 2017.

(51) Int. Cl. B64D 13/00; B64C 39/02; B60K 11/08; B64C 1/38

(52) U.S. Cl. CPC B64D 13/006; B64C 39/024; B60Y 2200/51; B64C 1/38; B64D 2221/00; B60K 11/08

(57) ABSTRACT

An unmanned aerial vehicle (UAV) includes a vehicle body and a flight control circuit. The vehicle body includes a housing and a fan. The housing includes two vents arranged at two ends of the housing and in communication with an internal space of the housing. The two vents and the internal space form a heat dissipation air passage. The fan is arranged at one of the two vents, and is configure to drive external air into the heat dissipation air passage and expel internal air from the heat dissipation air passage. The flight control circuit is arranged inside the housing and is configured to control flight parameters of the UAV. The heat dissipation air passage is configured to dissipate heat generated by the flight control circuit.

### CROSS-REFERENCE TO RELATED APPLICATION

This application is a continuation of International Application No. PCT/CN2017/074819, filed on Feb. 24, 2017, the entire content of which is incorporated herein by reference.

### TECHNICAL FIELD

The present disclosure relates to aircraft thermal dissipation technology, and in particular to a vehicle body and an unmanned aerial vehicle.

### BACKGROUND

When an unmanned aerial vehicle (UAV) is working, internal electronic components generate a lot of heat and cause the temperature inside the UAV to rise. Heat accumulation reduces an efficiency of the internal electronic components, affects a normal operation of the UAV, and even burns the UAV.

### SUMMARY

In accordance with the disclosure, there is provided an unmanned aerial vehicle (UAV) including a vehicle body and a flight control circuit. The vehicle body includes a housing and a fan. The housing includes two vents arranged at two ends of the housing and in communication with an internal space of the housing. The two vents and the internal space form a heat dissipation air passage. The fan is arranged at one of the two vents, and is configure to drive external air into the heat dissipation air passage and expel internal air from the heat dissipation air passage. The flight control circuit is arranged inside the housing and is configured to control flight parameters of the UAV. The heat dissipation air passage is configured to dissipate heat generated by the flight control circuit.

### BRIEF DESCRIPTION OF THE DRAWINGS

In order to illustrate the technical solutions of the present disclosure, the drawings used in the description of embodiments will be briefly described.

FIG. 1 is a schematic plan view of an example unmanned aerial vehicle (UAV) consistent with the disclosure.

FIG. 2 is a schematic cross-sectional view of the UAV in FIG. 1 along a line II-II consistent with the disclosure.

FIG. 3 is a schematic plan view of an example protection assembly of a UAV consistent with the disclosure.

FIG. 4 is a schematic cross-sectional view of the protection assembly in FIG. 3 along a line IV-IV consistent with the disclosure.

FIG. 5 schematically shows a flow direction of an air flow in the protection assembly in FIG. 3 consistent with the disclosure.

FIG. 6 schematically shows an internal-wind-speed simulation map of a UAV in a simulation project 1 consistent with the disclosure.

FIG. 7 schematically shows another internal-wind-speed simulation map of a UAV in the simulation project 1 consistent with the disclosure.

FIG. 8 schematically shows an internal-wind-speed simulation map of a UAV in a simulation project 2 consistent with the disclosure.

FIG. 9 schematically shows another internal-wind-speed simulation map of a UAV in the simulation project 2 consistent with the disclosure.

FIG. 10 schematically shows an internal-wind-speed simulation map of a UAV in a simulation project 3 consistent with the disclosure.

FIG. 11 schematically shows another internal-wind-speed simulation map of a UAV in the simulation project 3 consistent with the disclosure.

FIG. 12 schematically shows an internal-wind-speed simulation map of a UAV in a simulation project 4 consistent with the disclosure.

FIG. 13 schematically shows another internal-wind-speed simulation map of a UAV in the simulation project 4 consistent with the disclosure.

### DESCRIPTION OF MAIN COMPONENTS AND REFERENCE NUMERALS

| | |
|---|---|
| Unmanned aerial vehicle (UAV) | 100 |
| Vehicle body | 10 |
| Housing | 12 |
| Vent | 121 |
| Front end | 122 |
| Air inlet | 1222 |
| Rear end | 124 |
| Air outlet | 1242 |
| Heat dissipation air passage | 126 |
| Fan | 14 |
| Protection assembly | 16 |
| Partition board | 162 |
| Main board | 1622 |
| Vent hole | 1622a |
| Shielding piece | 1624 |
| Air guiding passage | 1626 |
| Mesh filter | 164 |
| First mounting member | 1641 |
| Through hole | 1642 |
| Second mounting member | 1643 |
| Venting member | 1644 |
| casing | 166 |
| Strip-shaped hole | 1662 |
| Arm | 18 |

### DETAILED DESCRIPTION OF THE EMBODIMENTS

Hereinafter, example embodiments will be described with reference to the accompanying drawings, in which the same numbers refer to the same or similar elements unless otherwise specified. It is intended that the embodiments disclosed herein are for illustration and not to limit the scope of the disclosure.

The terms “center,” “longitudinal,” “transverse,” “length,” “width,” “thickness,” “upper,” “lower,” “front,” “back,” “left,” “right,” “perpendicular,” “horizontal,” “top,” “bottom,” “inner,” “outer,” “clockwise,” “counterclockwise,” and similar expressions used herein are merely illustrative, e.g., indicating orientation or positional relationships shown in the disclosed drawings, and are not intended to indicate or imply that the apparatus or component referred to has a particular orientation or need to be constructed and operated in the particular orientation. It is not intended to limit the scope of the disclosure. The terms “first,” “second,” or the like in the specification, claims, and the drawings of the disclosure are merely illustrative, e.g. distinguishing similar elements, defining technical features, or the like, and are not intended to indicate or imply the importance of the corresponding elements or the number of the technical features. Thus, features defined as “first” and “second” may explicitly or implicitly include one or more of the features. As used herein, “a plurality of” means two or more, unless there are other clear and specific limitations.

As used herein, the terms “mounted,” “coupled,” and “connected” should be interpreted broadly, unless there are other clear and specific limitations. For example, the connection between two assemblies may be a fixed connection, a detachable connection, or an integral connection. The connection may also be a mechanical connection, an electrical connection, or a mutual communication connection. Furthermore, the connection may be a direct connection or an indirect connection via an intermedium, an internal connection between the two assemblies or an interaction between the two assemblies. The specific meanings of the above terms in the present disclosure can be understood by those skilled in the art on a case-by-case basis.

As used herein, unless otherwise defined, when a first component is referred to as “above” or “below” a second component, it is intended that the first component may be directly attached to the second component or may be indirectly attached to the second component via another component. When the first component is referred to as “over,” “above,” or “on top of” the second component, it is intended that the first component may be directly above or obliquely above the second component, or merely that a horizontal height of the first component may be higher than a horizontal height of the second component. When the first component is referred to as “below,” “under,” or “lower than” the second component, it is intended that the first component may be directly below or obliquely below the second component, or merely that the horizontal height of the first component may be lower than the horizontal height of the second component.

Various example embodiments corresponding to different structures of the disclosure will be described. For simplification purposes, the elements and configurations for the example embodiments are described below. It will be appreciated that the described embodiments are examples only and not intended to limit the scope of the disclosure. Moreover, the repeating of reference numbers or reference letters in various example embodiments are merely for the purposes of clarification and simplification, and does not indicate the relationship between the various example embodiments and/or configurations. In addition, the use of other processes and/or materials will be apparent to those skilled in the art from consideration of the examples of various specific processes and materials disclosed herein.

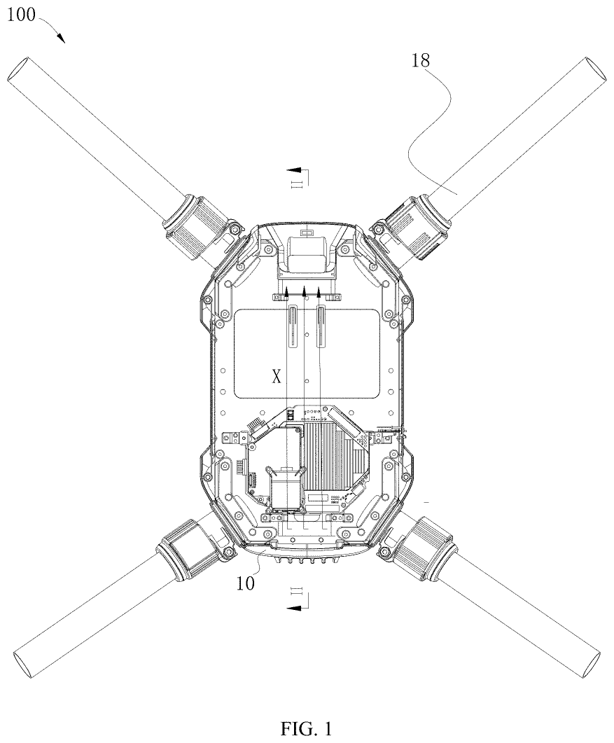

FIG. 1 is a schematic plan view of an example unmanned aerial vehicle (UAV) 100 consistent with the disclosure. The UAV 100 includes a vehicle body 10 and a flight control circuit (not shown in FIG. 1).

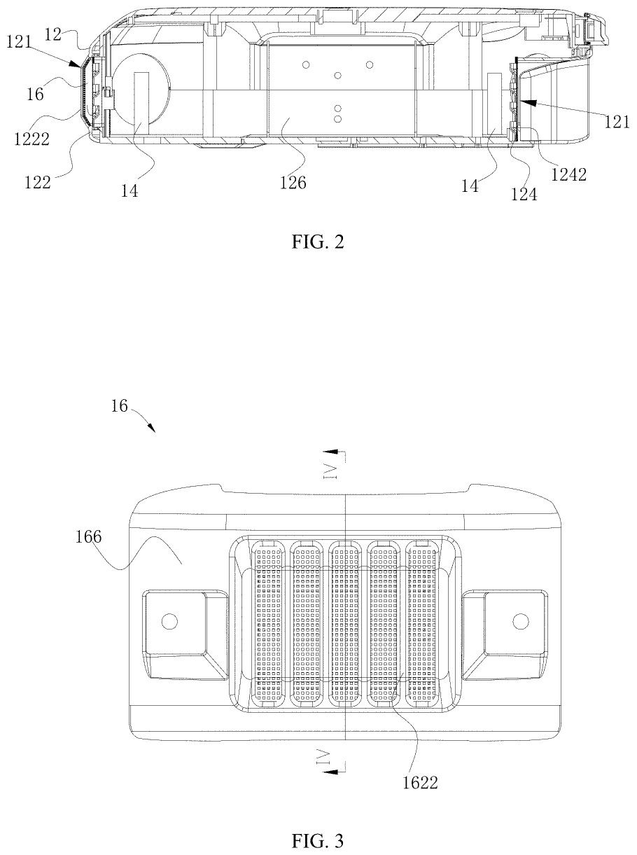

FIG. 2 is a schematic cross-sectional view of the UAV 100 along a line II-II consistent with the disclosure. As shown in FIGS. 1 and 2, the vehicle body 10 includes a housing 12, fan(s) 14, a protection assembly 16, and arm(s) 18. In some embodiments, the housing 12 may refer to a housing of a central body of the UAV 100. The fan(s) 14 and the protection assembly 16 can be mounted at the housing 12. In some embodiments, the vehicle body 10 can include a plurality of arms 18 fixedly connected to outer sides of the housing 12.

Each end of the housing 12 includes a vent 121 configured to communicate with an internal space of the housing 12 to form a heat dissipation air passage 126. The two vents 121 include an air inlet 1222 and an air outlet 1242. The air inlet 1222 is arranged at a front end 122 of the housing 12, and the air outlet 1242 is arranged at a rear end 124 of the housing 12. The front end 122 and the rear end 124 are opposite to each other. In some embodiments, as shown in FIG. 2, the front end 122 is in front of the rear end 124 along a flying direction of the UAV 100. For example, the front end 122 can be an end where a nose of the UAV 100 is located when the UAV 100 is in flight, and the rear end 124 can be an end where a tail of the UAV 100 is located when the UAV 100 is in flight. In some embodiments, the front end 122 and the rear end 124 can be arranged at positions different from the positions described above. For example, the front end 122 and the rear end 124 can be arranged at opposite sides of the vehicle body 10 of the UAV 100. According to an actual situation, the air inlet 1222 and the air outlet 1242 can be arranged at any suitable positions, as long as a route that the heat dissipation air passage 126 traverses can pass through heat-generating electronic components inside the housing 12.

The fan(s) 14 can be arranged at the vent(s) 121, and can be configured to face or not face the corresponding vent 121. The fan(s) 14 can be configured to guide external air of the housing 12 into the heat dissipation air passage 126, and guide internal air of the housing 12 to be discharged from the heat dissipation air passage 126. In some embodiments, the fan 14 can be arranged at the air inlet 1222, and configured to suck the external air into the heat dissipation air passage 126. In some embodiments, the fan 14 can be arranged at the air outlet 1242 and configured to discharge the internal air to outside of the housing 12. In some embodiments, the two fans 14 can be arranged at the air inlet 1222 and the air outlet 1242, and configured to suck the external air into the heat dissipation air passage 126 and discharge the internal air to the outside of the housing 12. The two fans 14 can also be referred to as a first fan and a second fan, respectively. That is, the vehicle body 10 can include only one fan 14 arranged at the air inlet 1222 or at the air outlet 1242, or the vehicle body 10 can include two fans 14 arranged at the air inlet 1222 and the air outlet 1242, respectively. The fan 14 at the air inlet 1222 can be configured to suck the air into the heat dissipation air passage 126, and the fan 14 at the air outlet 1242 can be configured to discharge the internal air to the outside of the housing 12, such that an air circulation can be formed. A flow direction of an air flow is indicated by an arrow X in FIG. 1. Arranging the two fans 14 at the air inlet 1222 and the air outlet 1242 can result in a better air circulation. The external air can flow more easily into the heat dissipation air passage 126 under a guidance of the fan(s) 14. The fan(s) 14 can help to accelerate the air flow, discharge more heat, and enhance the heat dissipation effect.

Table 1 is a list of temperatures of various electronic components in the UAV 100 for simulation projects 1 to 4. External environments of the simulation projects 1 to 4 are different, but internal conditions are the same. The internal conditions of the simulation projects 1 to 4 in Table 1 can be that a heat radiator is arranged inside the housing 12, and a heat sink of the heat radiator has a tooth height of 8.5 mm.

TABLE 1

| | | | | | Simulation |
|---|---|---|---|---|---|
| | | | Simulation | Simulation | project 4 (two fans |
| | | Simulation | project 2 (one fan | project 3 (one fan | 14 arranged at the |
| Name of the | | project 1 | 14 arranged at | 14 arranged at | air inlet 1222 and |
| electronic | Temperature | (no fan | the air outlet | the air inlet | the air outlet 1242, |
| component | limit | included) | 1242) | 1222) | respectively) |
| Environment | 45 | 45.0 | 45.0 | 45.0 | 45.0 |
| temperature | | | | | |
| LDO_tps7a7 | Tc: 105 | 215.9 | 73.4 | 78.0 | 70.7 |
| DDR4 | Tc: 85 | 228.3 | 73.4 | 79.3 | 72.5 |
| DDR4 | Tc: 85 | 209.0 | 68.4 | 74.3 | 65.8 |
| H1 | Tc: 85 | 222.0 | 81.4 | 85.3 | 81.4 |
| DDR4 | Tc: 85 | 209.8 | 81.6 | 86.4 | 61.1 |
| PMU 1160 | Tc: 85 | 197.9 | 63.3 | 70.5 | 61.5 |
| SKY85809 | Tc: 125 | 213.3 | 83.4 | 90.5 | 83.2 |
| SKY85809 | Tc: 125 | 214.6 | 84.2 | 91.4 | 84.2 |
| LC1860 | Tc: 110 | 209.5 | 78.0 | 85.2 | 77.7 |
| AR8001 | Tc: 85 | 196.3 | 65.5 | 72.9 | 65.1 |
| FPGA | Tc: 100 | 216.0 | 73.8 | 78.1 | 69.6 |

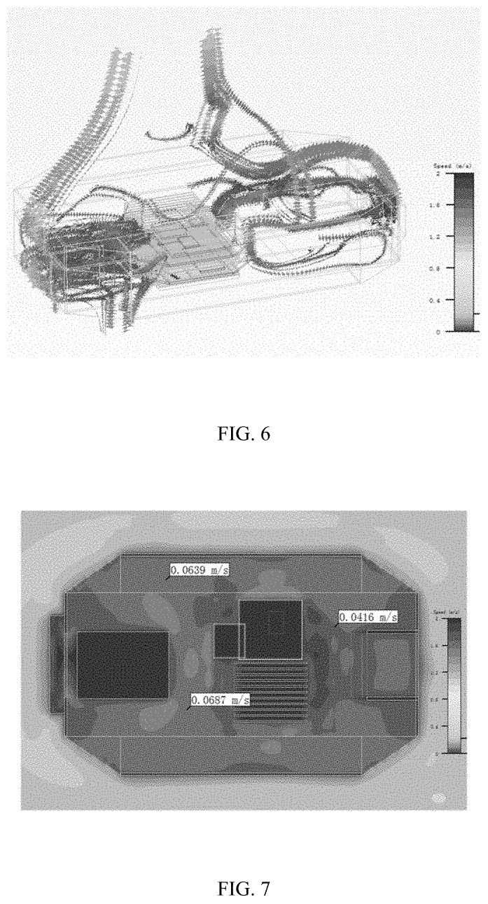

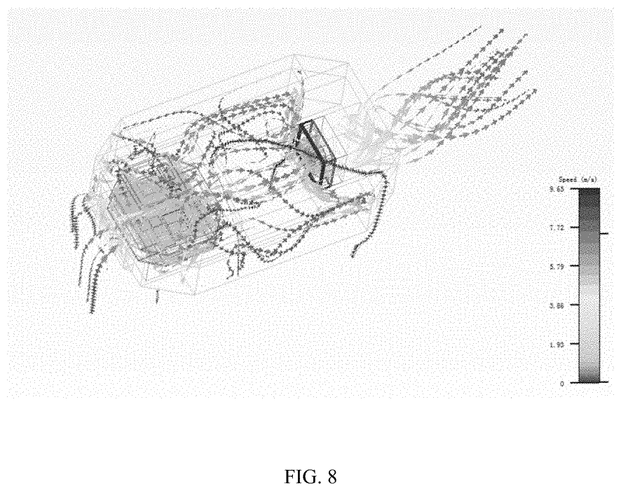

No fan is included in the simulation project 1. FIG. 6 schematically shows an example internal-wind-speed simulation map of the UAV 100 in the simulation project 1 consistent with the disclosure. FIG. 7 schematically shows another example internal-wind-speed simulation map of the UAV 100 in the simulation project 1 consistent with the disclosure. FIGS. 6 and 7 are simulation results of the simulation project 1. As shown in FIGS. 6 and 7, there is almost no air flow inside the housing 12, such that the heat generated by the electronic components inside the housing 12 can be easily accumulated inside the housing 12, resulting in an increase in the temperatures of the electronic components. As shown in a column corresponding to the simulation project 1 in Table 1, the temperature of each electronic component exceeds the temperature limit of each electronic component, such that a fatal hyperthermia risk may be caused.

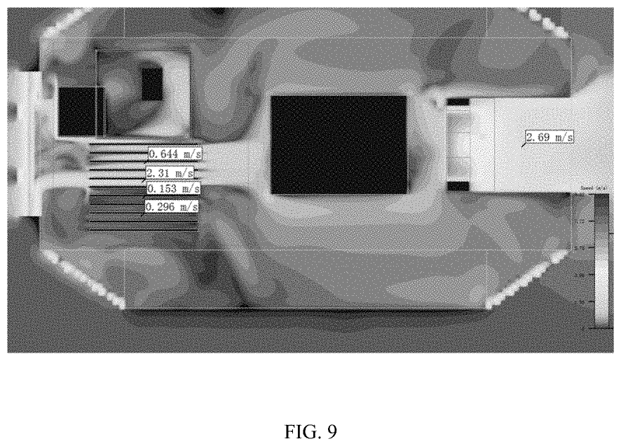

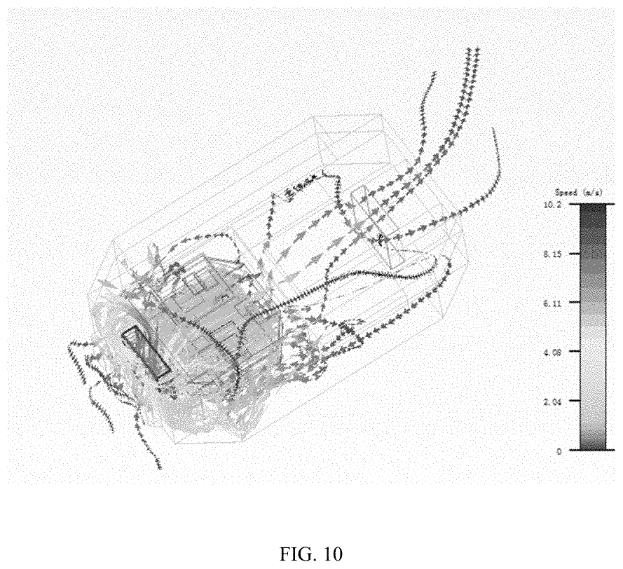

In the simulation project 2, the fan 14 is only arranged at the air outlet 1242. FIG. 8 schematically shows an internal-wind-speed simulation map of the UAV 100 in the simulation project 2 consistent with the disclosure. FIG. 9 schematically shows another internal-wind-speed simulation map of the UAV 100 in the simulation project 2 consistent with the disclosure. FIGS. 9 and 10 are simulation results of the simulation project 2. As shown in FIGS. 8 and 9, a wind speed of the air outlet 1242 is relatively large, such that the air flow inside the housing 12 can be accelerated, and the heat generated by some electronic components can be discharged to prevent the temperatures of the electronic components from continuously rising. As shown in a column corresponding to the simulation project 2 in Table 1, the temperature of each electronic component is greatly reduced relative to the temperature of each electronic component in the simulation project 1, and the temperature of each electronic component is lower than the corresponding temperature limit, such that the electronic components can work normally.

In the simulation project 3, the fan 14 is only arranged at the air inlet 1222. FIG. 10 schematically shows an internal-wind-speed simulation map of the UAV 100 in the simulation project 3 consistent with the disclosure. FIG. 11 schematically shows another internal-wind-speed simulation map of the UAV 100 in the simulation project 3 consistent with the disclosure. FIGS. 10 and 11 are simulation results of the simulation project 3. As shown in FIGS. 10 and 11, a wind speed of the air inlet 1222 is relatively large, such that the air flow inside the housing 12 can be accelerated, and the heat generated by some electronic components can be discharged to prevent the temperatures of the electronic components from continuously rising. As shown in a column corresponding to the simulation project 3 in Table 1, the temperature of each electronic component is greatly reduced relative to the temperature of each electronic component in the simulation project 1, and the temperature of each electronic component is lower than the corresponding temperature limit, such that the electronic components can work normally.

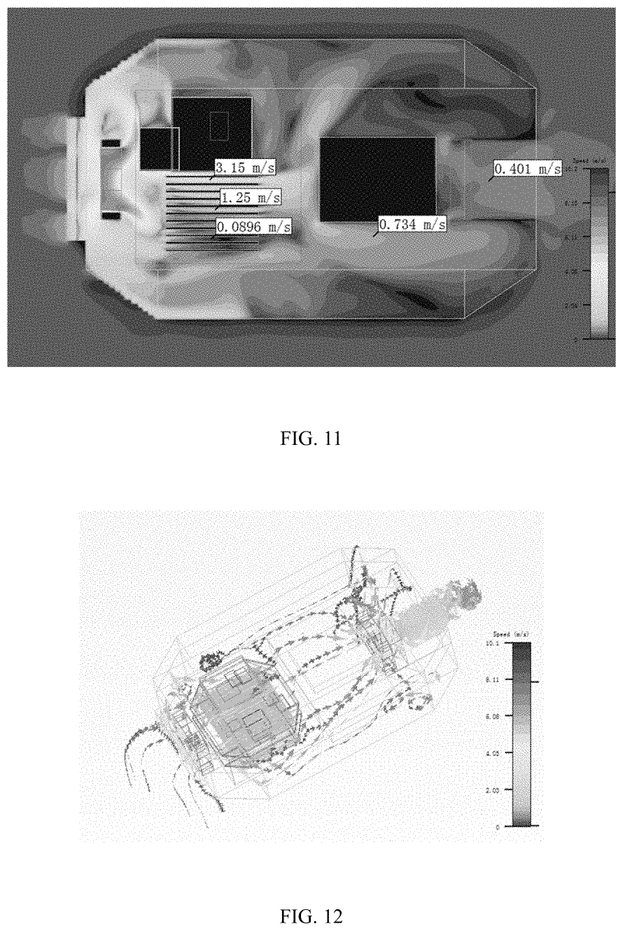

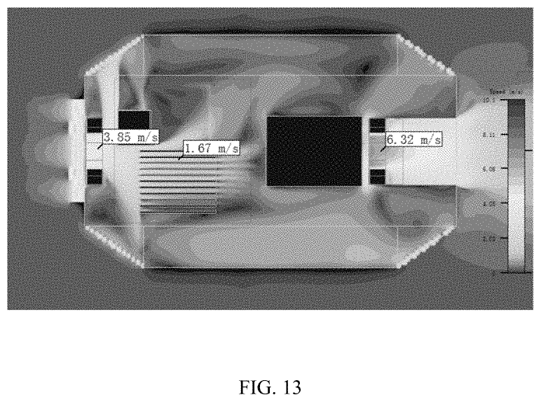

In the simulation project 4, two fans 14 are arranged at the air inlet 1222 and the air outlet 1242. FIG. 12 schematically shows an internal-wind-speed simulation map of the UAV 100 in the simulation project 4 consistent with the disclosure. FIG. 13 schematically shows another internal-wind-speed simulation map of the UAV 100 in the simulation project 4 consistent with the disclosure. FIGS. 12 and 13 are simulation results of the simulation project 4. As shown in FIGS. 12 and 13, because the fans 14 are arranged at the air inlet 1222 and the air outlet 1242, a high-speed air flow can be provided by the fans 14 to quickly discharge the heat generated by the electronic components inside the housing 12, thereby keeping the electronic components in a relatively low temperature range. As such, the temperature of each electronic component is below the corresponding temperature limit, and the hyperthermia risk can be avoided and the electronic components can work normally.

As shown in Table 1, a comparison of the simulation project 2 having one fan 14 arranged at the air outlet 1242, the simulation project 3 having one fan 14 arranged at the air inlet 1222, and the simulation project 4 having two fans 14 arranged at the air inlet 1222 and the air outlet 1242, respectively, shows that the temperatures of the electronic components inside the housing 12 in simulation project 4 are lower than the temperatures of the electronic components inside the housing 12 in simulation projects 2 and 3. That is, when the two fans 14 are arranged at the air inlet 1222 and the air outlet 1242, respectively, the ventilation and heat dissipation effect is the best.

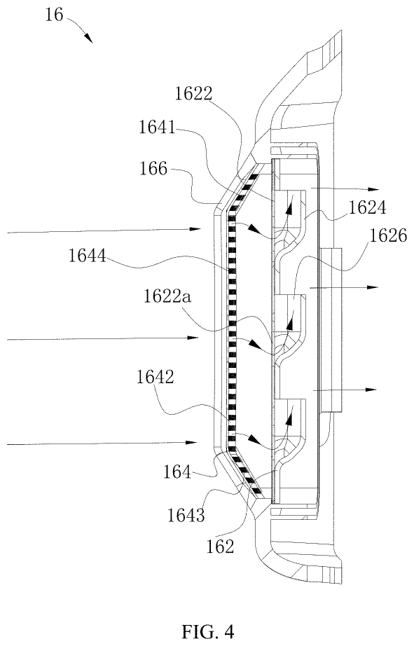

FIG. 3 is a schematic plan view of an example protection assembly 16 of the UAV 100 consistent with the disclosure. FIG. 4 is a schematic cross-sectional view of the protection assembly 16 along a line IV-IV consistent with the disclosure. As shown in FIGS. 2 to 4, the protection assembly 16 is arranged at the vent(s) 121 and configured to block impurities mixed in the external air, for example, dust, water droplets, and/or the like. In some embodiments, the protection assembly 16 can be only arranged at the air inlet 1222. The protection assembly 16 includes a partition board 162, a mesh filter 164, and a casing 166.

As shown in FIG. 4, the partition board 162 includes a main board 1622 and a plurality of shielding pieces 1624 extending from the main board 1622. The plurality of shielding pieces 1624 and the main board 1622 may be integrally connected or detachably connected. In some embodiments, the plurality of shielding pieces 1624 can be detachably connected to the main board 1622 to facilitate cleaning and replacement. Each shielding piece 1624 can have an approximately zigzag shape, and an air guiding passage 1626 having a bend shape can be formed by the adjacent two shielding pieces 1624. The main board 1622 includes a plurality of vent holes 1622a, and each shielding piece 1624 can be arranged align with the corresponding vent hole 1622a to block dust or/and water droplets blown into the corresponding vent hole 1622a from a front of the corresponding vent hole 1622a. When the external air enters the protection assembly 16, since each shielding piece 1624 has the zigzag shape, the impurities, for example, dust, water droplets, and/or the like, mixed in the external air can be easily attached to the shielding pieces 1624 due to inertia, thereby preventing the impurities, for example, dust, water droplets, and/or the like, from entering the inside of the housing 12.

As shown in FIG. 4, the mesh filter 164 can be arranged at a side of the partition board 162 distal from an interior of the housing 12. In some embodiments, the main board 1622 can be arranged closer to the mesh filter 164 than the plurality of shielding pieces 1624. The mesh filter 164 includes a plurality of through holes 1642. A maximum size of the plurality of through holes 1642 is smaller than a minimum size of the plurality of the vent holes 1622a of the partition board 162. In some embodiments, sizes of the plurality of through holes 1642 can be the same, and sizes of the plurality of vent holes 1622a can be also the same. In this way, the size of the plurality of through holes 1642 can be smaller than the size of the plurality of vent holes 1622a. In some embodiments, the sizes of some of the plurality of through holes 1642 may be the same, and the sizes of some of the plurality of vent holes 1622a may be the same. In this way, the corresponding size (e.g., the maximum size) of a largest through hole 1642 among the plurality of through holes 1642 can be smaller than the corresponding size (e.g., the minimum size) of a smallest vent hole 1622a among the plurality of vent holes 1622a. The plurality of through holes 1642 in the mesh filter 164 can be configured to filter smaller impurities in the air. Setting the maximum size of the plurality of through holes 1642 to be smaller than the minimum size of the plurality of vent holes 1622a of the partition board 162 can minimize a wind resistance after filtering small impurities in the air, increase an amount of air entering the heat dissipation air passage 126, and improve the heat dissipation efficiency of each electronic component in the housing 12. The mesh filter 164 includes a first mounting member 1641, a second mounting member 1643, and a venting member 1644 connected between the first mounting member 1641 and the second mounting member 1643. The first mounting member 1641 and the second mounting member 1643 can be mounted on the housing 12 at positions corresponding to opposite ends of the vent 121, and the venting member 1644 protrudes toward the outside of the housing 12 with respect to the partition board 162 (e.g., the venting member 1644 can have a convex structure, for example, the mesh filter 164 can have a central-convex structure, i.e., a central portion of the mesh filter 164 can be convex). For example, a width of the mesh filter 164 can be gradually increased along a direction approaching the heat dissipation air passage 126, such that the UAV 100 can experience less resistance during flight.

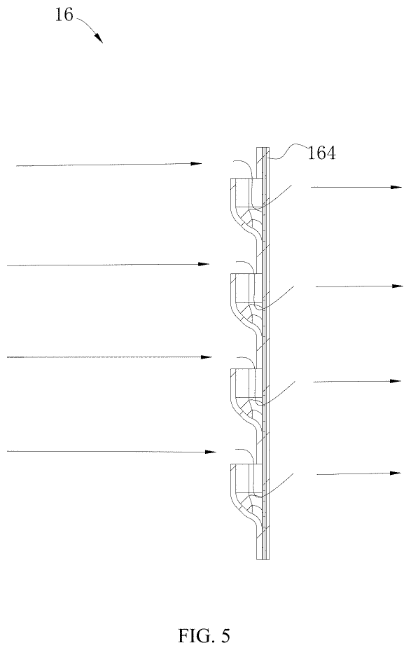

As shown in FIG. 3, the casing 166 includes a plurality of strip-shaped holes 1662. A minimum size, such as a minimum width, of the plurality of strip-shaped holes 1662 is larger than a maximum size, such as a maximum diameter, of the plurality of through-holes 1642 of the mesh filter 164. In some embodiments, sizes of the plurality of strip-shaped holes 1662 can be the same, and sizes of the plurality of through holes 1642 can also be the same. In this way, the size of the plurality of through holes 1642 can be smaller than the size of the plurality of strip-shaped holes 1662. In some embodiments, the sizes of some of the plurality of through holes 1642 may be the same, and the sizes of some of the plurality of strip-shaped holes 1662 may be the same. In this way, the corresponding size (e.g., the maximum size) of a largest through hole 1642 among the plurality of through holes 1642 can be smaller than the corresponding size (e.g., the minimum size) of a smallest strip-shaped hole 1662 among the plurality of strip-shaped holes 1662. The casing 166 is an outermost layer of the protection assembly 16. The minimum size of the plurality of strip-shaped holes 1662 is larger than the maximum size of the plurality of through holes 1642 of the mesh filter 164, such that the plurality of strip-shaped holes 1662 can filter out large impurities in the external air, therefore protecting the mesh filter 164 and other structures within the housing 12. In some embodiments, the mesh filter 164 can be arranged inside the housing 12. A shape of the casing 166 corresponds to the shape of the mesh filter 164, and hence the mesh filter 164 can be arranged close to the casing 166. In some embodiments, the casing 166 and the housing 12 can be one-piece molded. The casing 166, the mesh filter 164, the partition board 162, and the fan 14 can be arranged in order from the outside of the housing 12 to the inside of the housing 12. That is, when entering the inside of the housing 12, the external air passes through the casing 166, the mesh filter 164, the partition board 162, and the fan 14 in order. When entering the inside of the housing 12, the external air passes through the plurality of strip-shaped holes 1662, the plurality of through holes 1642, the plurality of vent holes 1622a, and the air guiding passage 1626 in order. FIG. 5 schematically shows a flow direction of an air flow in the protection assembly 16 consistent with the disclosure. The protection assembly 16 can be arranged, for example, at the rear end 124 of the housing 12. The direction of air flow is shown by the arrows in FIGS. 4 and 5. The relatively large impurities mixed in the external air can be filtered out when the external air passes through the plurality of strip-shaped holes 1662, and then the relatively small impurities can be filtered out via the plurality of through holes 1642, and finally the external air can be guided through the vent hole 1622a to enter into the air guiding passage 1626. The fine dust, water droplets, and/or the like, in the air can be further filtered in the air guiding passage 1626, such that the protection assembly 16 can have a waterproof and dustproof function.

The flight control circuit can be arranged inside the housing 12 and configured to control flight parameters of the UAV 100. The heat dissipation air passage can be used to dissipate the heat generated by the flight control circuit. For example, the flight control circuit can include a circuit board and electronic components arranged on the circuit board. The electronic components can include at least one of a flight controller, an inertial measurement unit (IMU), or a power management controller. The electronic components described above may generate a large amount of heat during operation. When the external air enters the inside of the housing 12, due to the convective heat transfer, a large amount of heat can be discharged to prevent the electronic components from being overheated due to heat accumulation.

According to the UAV 100 disclosed in the embodiments, the external air can pass through the protection assembly 16 to remove impurities, for example, dust, water droplets, or/and the like, mixed in the air, and then enters the inside of the housing 12. Due to the convective heat transfer between the air flow and the electronic components in the housing 12, a large amount of heat can be discharged to avoid excessive temperature rise of electronic components.

In the vehicle body 10 or the UAV 100, each end of the housing 12 can include the vent 121 configured to communicate with the internal space of the housing 12 to form the heat dissipation air passage 126, and the fan(s) 14 can be arranged at the vent(s) 121 to guide the external air of the housing 12 into the heat dissipation air passage 126, and guide the internal air of the housing 12 to be discharged from the heat dissipation air passage 126. As such, a better ventilation can be achieved inside the housing 12, and the heat generated by the electronic components inside the housing 12 can be discharged in time to avoid a reduction of a working efficiency of the electronic components, thereby ensuring a normal operation of the UAV 100 and extending a service life of the UAV 100.

In some embodiments, the protection assembly 16 can include the partition board 162, the mesh filter 164, and the casing 166. The protection assembly 16 can prevent impurities, for example, dust, water droplets, and/or the like, from entering the inside of the housing 12 with the outside air, and prevent impurities, for example, dust, water droplets, and/or the like, from adhering to the electronic components inside the housing 12, thereby ensuring the normal operation of the UAV 100.

In some embodiments, the mesh filter 164 can be arranged inside the housing 12. The shape of the casing 166 corresponds to the shape of the mesh filter 164, and hence the mesh filter 164 can be arranged close to the casing 166. The casing 166 can protect the mesh filter 164.

In some embodiments, the air inlet 1222 can be arranged at the front end 122 of the housing 12, and thus the air inlet 1222 can be in front of the air outlet 1242 along the flying direction of the UAV 100, such that the external air can be more easily to enter the inside of the housing 12, thereby further enhancing the heat dissipation of the electronic components inside the housing 12.

In some embodiments, the mesh filter 164 and/or the casing 166 in the protection assembly 16 may be omitted. In some embodiments, the protection assembly 16 can be arranged only at the air outlet 1242.

In some embodiments, as shown in, e.g., FIGS. 2 and 5, the UAV 100 includes two protection assemblies 16 arranged at the air inlet 1222 and the air outlet 1242, respectively. The two protection assemblies can also be referred to as a first protection assembly and a second protection assembly, respectively. The mesh filter 164 of the protection assembly 16 arranged at the air inlet 1222 can have the central-convex structure along the direction approaching the heat dissipation air passage 126, and the mesh filter 164 of the protection assembly 16 arranged at the air outlet 1242 can have a plan structure.

In some other embodiments, the structure of the mesh filter 164 of the protection assembly 16 arranged at the air inlet 1222 and the structure of the mesh filter 164 of the protection assembly 16 arranged at the air outlet 1242 can be the same, for example, the convex structure or the plane structure described above.

As used herein, the terms “certain embodiment,” “an embodiment,” “some embodiments,” “an example,” “certain example,” “some examples,” or the like, refer to that the specific features, structures, materials, or characteristics described in connection with the embodiments or examples are included in at least one embodiment or example of the disclosure. The illustrative representations of the above terms are not necessarily referring to the same embodiments or examples. Furthermore, the specific features, structures, materials, or characteristics described may be combined in a suitable manner in any one or more embodiments or examples.

The terms “first,” “second,” or the like in the specification, claims, and the drawings of the disclosure are merely illustrative, e.g. distinguishing similar elements, defining technical features, or the like, and are not intended to indicate or imply the importance of the corresponding elements or the number of the technical features. Thus, features defined as “first” and “second” may explicitly or implicitly include one or more of the features. As used herein, “multiple” means two or more, unless there are other clear and specific limitations.

It is intended that the disclosed embodiments be considered as exemplary only and not to limit the scope of the disclosure. Changes, modifications, alterations, and variations of the above-described embodiments may be made by those skilled in the art within the scope of the disclosure. The scope of the invention is defined by the following claims.

What is claimed is:

1. An unmanned aerial vehicle (UAV) comprising:
a vehicle body including:
a housing including:
two vents arranged at two ends of the housing and in communication with an internal space of the housing, the two vents and the internal space forming a heat dissipation air passage; and
a fan arranged at one of the two vents and configure to drive external air into the heat dissipation air passage, and expel internal air from the heat dissipation air passage; and
a flight control circuit arranged inside the housing and configured to control flight parameters of the UAV;
wherein the heat dissipation air passage is configured to dissipate heat generated by the flight control circuit.

2. The UAV of claim 1, wherein the two vents include:
an air inlet arranged at a front end of the housing; and
an air outlet arranged at a rear end of the housing.

3. The UAV of claim 2, wherein:
the fan is arranged at the air inlet and configured to suck the external air into the heat dissipation air passage; or
the fan is arranged at the air outlet and configured to discharge the internal air to outside of the housing.

4. The UAV of claim 2, wherein:
the fan is a first fan arranged at the air inlet and configured to suck the external air into the heat dissipation air passage; and
the vehicle body further includes a second fan arranged at the air outlet and configured to discharge the internal air to outside of the housing.

5. The UAV of claim 1, wherein the vehicle body further includes:
a protection assembly arranged at the one of the two vents.

6. The UAV of claim 5, wherein the protection assembly includes:
a partition board including:
a main board including a plurality of vent holes; and
a plurality of shielding pieces extending from the main board, each of the shielding pieces being aligned with a corresponding one of the vent holes.

7. The UAV of claim 6, wherein the protection assembly further includes:
a mesh filter arranged at a side of the partition board distal from an interior of the housing and including a plurality of through holes, a maximum size of the plurality of through holes being smaller than a minimum size of the plurality of the vent holes.

8. The UAV of claim 7, wherein the protection assembly further includes:
a casing including a plurality of strip-shaped holes, a minimum size of the plurality of strip-shaped holes being larger than a maximum size of the plurality of through-holes of the mesh filter.

9. The UAV of claim 8, wherein the casing and the housing are one-piece molded.

10. The UAV of claim 7, wherein:
the main board is arranged closer to the mesh filter than the plurality of shielding pieces; and
the plurality of shielding pieces and the main board are one-piece molded or are detachably connected.

11. The UAV of claim 7, wherein the mesh filter includes:
a first mounting member;
a second mounting member; and
a venting member connected between the first mounting member and the second mounting member and protruding toward outside of the housing with respect to the partition board.

12. The UAV of claim 11, wherein the first mounting member and the second mounting member are mounted on the housing at positions corresponding to opposite ends of the corresponding vent.

13. The UAV of claim 7, wherein a width of the mesh filter gradually increases along a direction towards the heat dissipation air passage.

14. The UAV of claim 5, wherein:
the two vents include an air inlet arranged at a front end of the housing and an air outlet arranged at a rear end of the housing; and
the protection assembly is arranged at the air inlet.

15. The UAV of claim 5, wherein:
the two vents include an air inlet arranged at a front end of the housing and an air outlet arranged at a rear end of the housing;
the protection assembly is a first protection assembly arranged at the air inlet; and
the vehicle body further includes a second protection assembly arranged at the air outlet.

16. The UAV of claim 15, wherein:
a mesh filter of the first protection assembly has a central-convex structure protruding towards the heat dissipation air passage; and
a mesh filter of the second protection assembly has a plan structure.

17. The UAV of claim 1, wherein the flight control circuit includes:
a circuit board; and
an electronic component arranged on the circuit board and including at least one of a flight controller, an inertial measurement unit (IMU), or a power management controller.
